(19) United States
(12) Patent Application Publication
(10) Pub. No.: US 2026/0147032 A1
(43) Pub. Date: May 28, 2026

(54) DEVICE AND METHOD FOR TESTING AN ELECTRONIC COMPONENT

(71) Applicant: CENTRUM TECHNOLOGY CORP., Taoyuan (TW)

(72) Inventors: Tony-Yi CHUANG, Taoyuan (TW); Hao-Wei Hsu, Taoyuan (TW)

(73) Assignee: CENTRUM TECHNOLOGY CORP., Taoyuan (TW)

(21) Appl. No.: 19/190,130

(22) Filed: Apr. 25, 2025

(30) Foreign Application Priority Data
Nov. 27, 2024 (TW) 113145862

(51) Int. Cl. G01R 31/28

(52) U.S. Cl. CPC G01R 31/281; G01R 31/2887; G01R 31/2891

(57) ABSTRACT

A device for testing an electronic component is disclosed. The device includes a heating module and a temperature monitoring module. The heating module is configured to heat the electronic component. The temperature monitoring module is electrically connected to the heating module, and configured to monitor and control a temperature of the electronic component.

### CROSS-REFERENCE TO RELATED APPLICATION AND CLAIM OF PRIORITY

The application claims the benefit of Taiwan Application No. 113145862, filed on Nov. 27, 2024, at the TIPO, the disclosures of which are incorporated herein in their entirety by reference.

### FIELD OF THE INVENTION

The present invention is related to a device and method for testing a component, and more particularly to a device and method for testing an electronic component.

### BACKGROUND OF THE INVENTION

Electronic components, such as printed circuit boards (PCBs), wafers, liquid crystal panels, IC carrier boards, and other products that require heating and electrical testing, usually have circuits and circuit nodes arranged on the circuits. Several electronic components are electrically connected to several circuit nodes, and then the electronic components are electrically controlled by the circuit. The above-mentioned electronic components are widely used in various electronic products.

The circuit nodes of the electronic component, such as the printed circuit board, may not be able to conduct normally, or have poor contact when heated due to insufficient thickness, cracking, or peeling of the metal layer, or other factors. Therefore, the manufacturer will test the circuit nodes of the printed circuit board before shipping the printed circuit board. However, the traditional circuit node testing uses a method of heating a printed circuit board that is contacted by a ceramic heating structure, which results in only a part of the printed circuit board that is contacted by the ceramic heating structure being heated, while the other part of the printed circuit board that is not contacted by the ceramic heating structure is not heated, thereby causing problems such as the uneven heating and the inaccurate yield of the printed circuit board during the testing process.

In addition, the temperature detection of the electronic component to be tested, such as the PCB product, during heating is also very important. It is necessary to maintain a required temperature of the electronic component to be tested, while avoid high temperatures from burning the electronic component to be tested in order to improve the yield rate.

In order to overcome the drawbacks in the prior art, a device and method for testing an electronic component are disclosed. The particular design in the present invention not only solves the problems described above, but also is easy to implement. Thus, the present invention has utility for the industry.

### SUMMARY OF THE INVENTION

The present invention discloses a device and method for testing an electronic component. The device for testing the electronic component uses a heating module to heat the electronic component so that it can evenly heat the electronic component, and improve the detection accuracy and yield.

The present invention further discloses a temperature monitoring unit for monitoring the temperature of the electronic component, and providing temperature data. The present invention further discloses a processing unit electrically connected to the temperature monitoring unit and a heating module. The processing unit can control the heating status of the heating module, and simultaneously obtain the temperature data related to the electronic component from the temperature monitoring unit. When performing the heating, the processing unit controls the heating status of the heating module, such as the heating intensity, in real time according to the temperature data so that the temperature of the electronic component can reach the required test temperature and be stable within a predetermined range. Compared with the traditional circuit node testing method that uses ceramics to contact the printed circuit board for heating, the traditional method is firstly to use a pair of ceramics to contact the printed circuit board, and then perform an electrical test on the circuit node. Only a single side can be tested, and then the two sides can be tested after the PCB leaves the ceramics. The device for testing the electronic component in the present invention can carry or clamp a part of the electronic component, such as the edge of the PCB, so that most of both sides of the PCB are exposed. Therefore, both sides of the PCB can be tested at the same time, and thus the PCB can be heated, and the electrical properties of both sides of the PCB (such as electrical impedance, capacitive reactance, inductive reactance, withstanding voltage, withstanding current, etc.) can be tested at the same time. This can not only reduce the detection time, but also improve the yield, and also reduce the probability of the same production batch being completely scrapped.

In accordance with one aspect of the present invention, a device for testing an electronic component is disclosed. The device includes a clamp, a heating module, a thermal imager and a processing unit. The clamp is configured to hold the electronic component having a first surface and a second surface being opposite to the first surface. The heating module is disposed at one side of the electronic component, and configured to heat the first surface. The thermal imager is disposed at an opposite side of the electronic component, and configured to monitor a temperature on the second surface of the electronic component. The processing unit is electrically connected to the heating module and the thermal imager, and configured to adjust the heating module in response to the temperature to stabilize the temperature within a predetermined range.

In accordance with another aspect of the present invention, a method for testing an electronic component is disclosed. The method includes the following steps: providing an electronic component having one side and an opposite side, a holder for holding the electronic component, a heating module disposed at the one side of the electronic component, a temperature monitoring unit disposed at the opposite side of the electronic component, and a processing unit; holding and moving the electronic component to a position in front of the heating module; heating a first surface of the electronic component using the heating module; monitoring a second surface of the electronic component using the temperature monitoring unit to monitor a temperature of the electronic component; and adjusting the heating module in response to the temperature to stabilize the temperature within a predetermined range.

In accordance with a further aspect of the present invention, a device for testing an electronic component is disclosed. The device includes a heating module and a temperature monitoring module. The heating module is configured to heat the electronic component. The temperature monitoring module is electrically connected to the heating module, and configured to monitor and control a temperature of the electronic component.

Based on the above, compared with the conventional heating method by using the ceramics to contact the electronic component, the device for testing the electronic component in the present invention adopts a heating method of irradiating a large area of the electronic component by a heating module. The first heating source of the heating module is disposed above the carrier, and capable of irradiating a large area of the upper surface of the electronic component. The second heating source of the heating module can be not disposed or disposed below the carrier, and capable of irradiating a large area of the lower surface of the electronic component. The heating module can make the electronic component evenly heated, thereby increasing the detection yield so that the device for testing the electronic component can evenly heat the electronic component, and improve the detection accuracy and yield.

The device for testing the electronic component in the present invention can also monitor the temperature of the electronic component so that the temperature of the electronic component can reach the required test temperature, and be stabilized in a predetermined range. This device and testing method can not only reduce the testing time, but also improve the yield, eliminate unreliable electronic components in advance before leaving the factory, and prevent normal electronic components from being damaged, thereby improving the yield, and reduce the potential cost of scrapping the entire batch.

The above objectives and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 is a flow chart of the steps of a method for testing an electronic component according to a preferred embodiment of the present invention;

FIG. 2 is a top view of a detection device for an electronic component according to a preferred embodiment of the present invention;

FIG. 3 is another top view of the detection device for the electronic component according to a preferred embodiment of the present invention;

FIG. 4 is a front view of the detection device for the electronic component according to a preferred embodiment of the present invention;

FIG. 5 is a schematic diagram showing the translation of the bearing frame relative to the heating module according to a preferred embodiment of the present invention;

FIG. 6 is another schematic diagram showing the translation of the bearing frame relative to the heating module according to a preferred embodiment of the present invention;

FIG. 7 is a further schematic diagram showing the translation of the bearing frame relative to the heating module according to a preferred embodiment of the present invention;

FIG. 8 is another schematic diagram showing the translation of the bearing frame relative to the heating module according to the present invention;

FIG. 9 is a schematic diagram of a method for testing an electronic component according to a preferred embodiment of the present invention;

FIG. 10 is a schematic diagram of a device for testing an electronic component according to a preferred embodiment of the present invention; and

FIG. 11 is a schematic diagram of a device for testing an electronic component according to another preferred embodiment of the present invention.

### DETAILED DESCRIPTION OF THE PREFERRED EMBODIMENTS

The present invention will now be described more specifically with reference to the following embodiments. It is to be noted that the following descriptions of preferred embodiments of this invention are presented herein for the purposes of illustration and description only; they are not intended to be exhaustive or to be limited to the precise form disclosed.

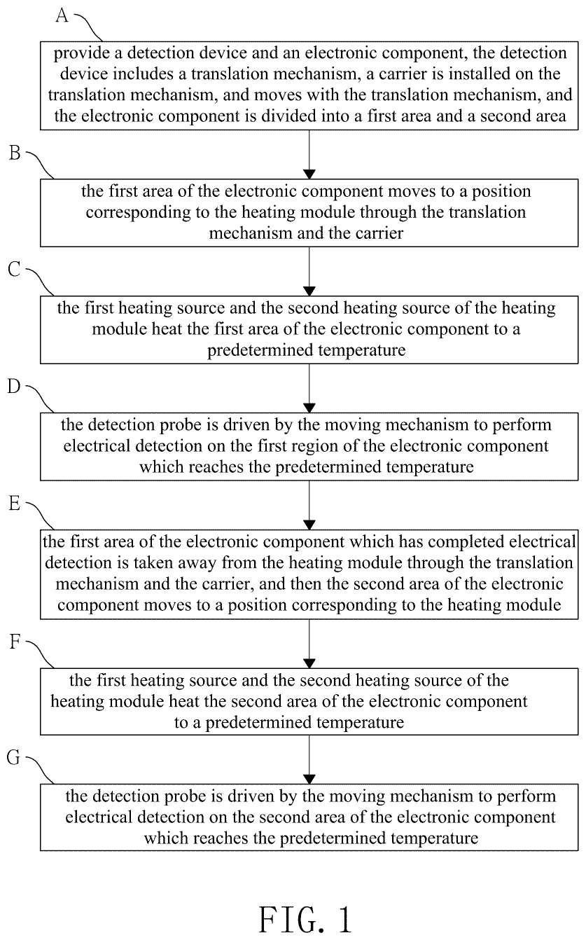

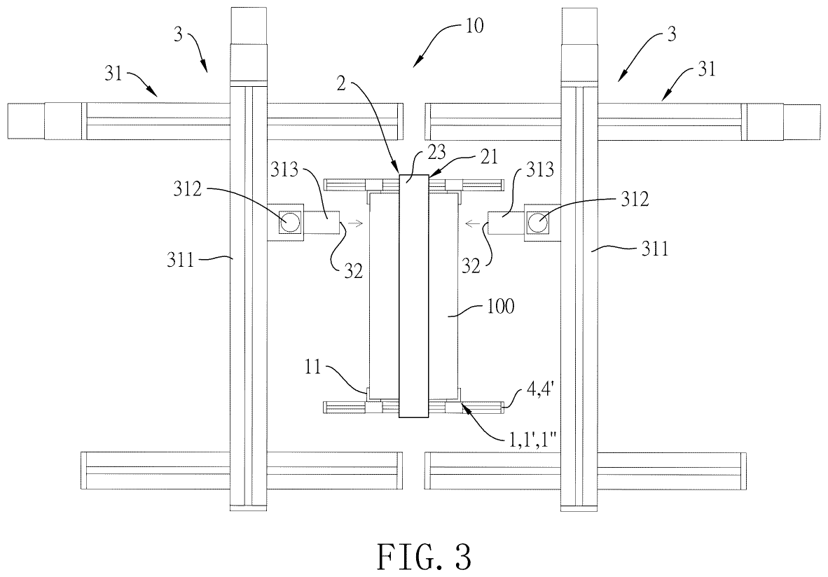

Please refer to FIGS. 1 to 8. The present invention discloses a detection device 10 for an electronic component 100, and a method for testing the electronic component 100. The detection device 10 for the electronic component 100 mainly includes a bearing frame 1, a heating module 2, and one or more detection modules 3.

As shown in FIGS. 1 to 6, the carrier 1 is used to carry the electronic component 100. The carrier 1 has a clearance area therein, and two opposite surfaces of the electronic component 100 are exposed through the clearance area.

As shown in FIGS. 1 to 6, the heating module 2 includes a first heating source 21 and a second heating source 22. The first heating source 21 is disposed at one side of the carrier 1, and irradiates one surface of the electronic component 100. The second heating source 22 is disposed at the other side of the carrier 1, and irradiates the other surface of the electronic component 100. The first heating source 21 and the second heating source 22 are disposed opposite to each other.

In addition, each of the first heating source 21 and the second heating source 22 has a halogen heating lamp 23. The halogen heating lamp 23 is preferably a gold halogen heating lamp. The gold halogen heating lamp has the advantages of being able to instantly rise to a high temperature of more than 500° C., high infrared radiation efficiency, strong horsepower, and fast heating speed. The special gold outer coating of the lamp can control the lamp to 1650 kelvin (temperature scale measurement unit), making it more eye-protective and non-glare-inducing. The main emission wavelength is between 0.8˜1.4 microns, the output can be adjusted through the controller, the price is economical, and the life is long lasting.

As shown in FIGS. 1 to 3, the detection module 3 includes a moving mechanism 31, and a detection probe 32 installed on the moving mechanism 31. The moving mechanism 31 is disposed corresponding to the carrier 1, and drives the detection probe 32 to test whether the circuit nodes of the electronic component 100 are normally connected or have bad contact.

The detailed description is as follows. The moving mechanism 31 includes a translation drive unit 311, a lift drive unit 312 installed on the translation drive unit 311, and a fixed base 313 installed on the lift drive unit 312. The detection probe 32 is fixed on the fixed base 313. The fixed base 313 moves up and down relative to the electronic component 100 through the lifting driving unit 312, and the lifting driving unit 312 translates left and right relative to the electronic component 100 through the translation driving unit 311.

The number of the detection modules 3 in this embodiment is four, but is not limited thereto. Two detection modules 3 are disposed on the left and right sides of one side of the carrier 1, and the other two detection modules 3 are disposed on the left and right sides of the other side of the carrier 1 so that the four detection probes 32 can detect the left and right sides of the upper surface, and the left and right sides of the lower surface of the electronic component 100.

As shown in FIGS. 1 to 6, the detection device 10 for the electronic component 100 of the present invention further includes a translation mechanism 4. The carrier 1 is installed on the translation mechanism 4, and can follow the translation mechanism 4 to move left and right relative to the first heating source 21 and the second heating sources 22.

In addition, the translation drive unit 311, the lifting drive unit 312 and the translation mechanism 4 can be common linear slide rails or motor-driven push rods, etc., and are not limited to the disclosure of the figures in this embodiment.

FIGS. 1 to 6 show the usage state of the detection device 10 for the electronic component in the present invention, wherein the detection device 10 uses the heating module 2 to heat the electronic component 100. The first heating source 21 is disposed above the carrier 1, and can irradiate a large area of the upper surface of the electronic component 100. The second heating source 22 is disposed below the carrier 1, and can irradiate a large area of the lower surface of the electronic component 100.

Therefore, compared with the conventional method of heating the electronic component by ceramic contact, the detection device 10 for the electronic component 100 in the present invention adopts a heating method of irradiating a large area of the electronic component 100 by the heating module 2 so that the electronic component 100 can be heated more evenly, thereby increasing the detection yield. Therefore, the detection device 10 for the electronic component 100 has the effects of uniformly heating the electronic component 100, and improving the detection accuracy and yield.

In addition, the first heating source 21 and the second heating source 22 respectively have halogen heating lamps 23 so that the heating module 2 has the advantages of instantaneous temperature rise, fast heating speed, high infrared radiation efficiency, an economical price, and a long life.

The method for inspecting electronic components of the present invention will be described below with reference to FIG. 1. The method for inspecting electronic components of the present invention includes the following steps.

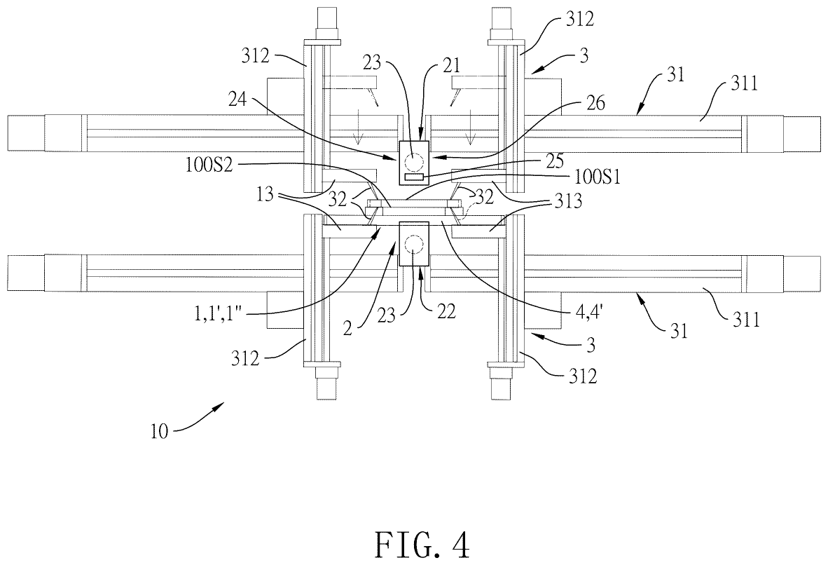

As shown in the step A of FIG. 1, FIGS. 4 to 5, and FIG. 7, the electronic component 100 is provided. The detection device 10 for the electronic component 100 further includes a translation mechanism 4. The carrier 1 is installed on the translation mechanism 4, and moves with the translation mechanism 4. The electronic component 100 is divided into a first area 101 and a second area 102.

As shown in the step B of FIG. 1, FIGS. 4 to 5, and FIG. 7, the first area 101 of the electronic component 100 moves to a position corresponding to the heating module 2 through the translation mechanism 4 and the carrier 1.

As shown in the step C of FIG. 1, FIGS. 4 to 5, and FIG. 7, the first heating source 21 and the second heating source 22 of the heating module 2 heat the first area 101 of the electronic component 100 to a predetermined temperature.

As shown in the step D of FIG. 1, FIGS. 4 to 5, and FIG. 7, the detection probe 32 is driven by the moving mechanism 31 to perform electrical detection on the first region 101 of the electronic component 100 which reaches the predetermined temperature.

As shown in the step E of FIG. 1, and FIGS. 4, 6, 8, the first area 101 of the electronic component 100 which has completed electrical detection is taken away from the heating module 2 through the translation mechanism 4 and the carrier 1. Then, the second area 102 of the electronic component 100 moves to a position corresponding to the heating module 2.

As shown in the step F of FIG. 1, and FIGS. 4, 6, 8, the first heating source 21 and the second heating source 22 of the heating module 2 heat the second area 102 of the electronic component 100 to a predetermined temperature.

As shown in the step G of FIG. 1, and FIGS. 4, 6, 8, the detection probe 32 is driven by the moving mechanism 31 to perform electrical detection on the second area 102 of the electronic component 100 which reaches the predetermined temperature.

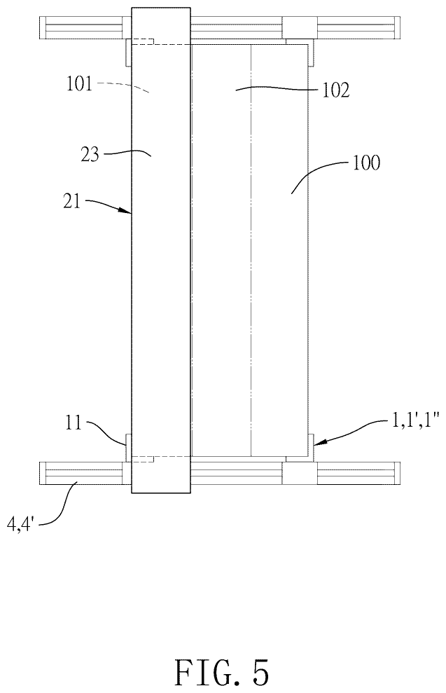

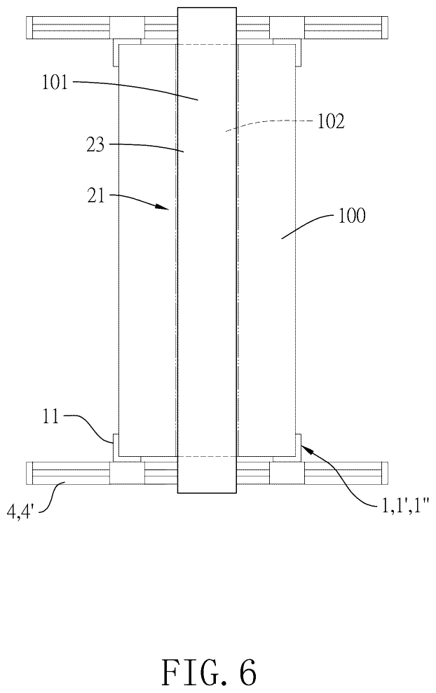

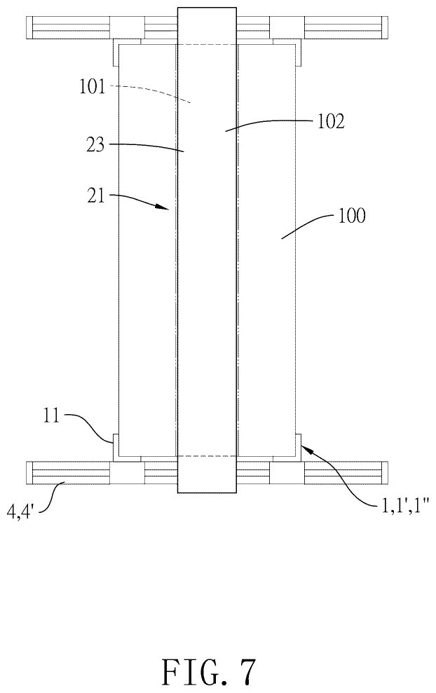

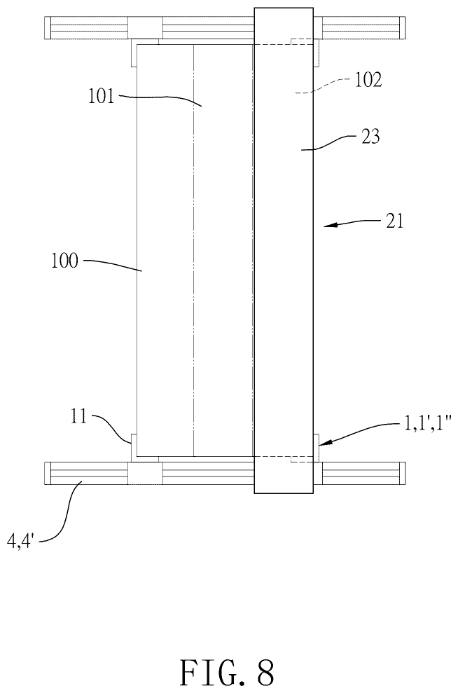

As shown in FIGS. 5 and 6, the first region 101 can be located at the left side of the electronic component 100, and the second region 102 can be located in the middle of the electronic component 100; alternatively, as shown in FIGS. 7 and 8, the first area 101 can be located in the middle of the electronic component 100, and the second area 102 can be located at the right side of the electronic component 100, which is not limited to this embodiment.

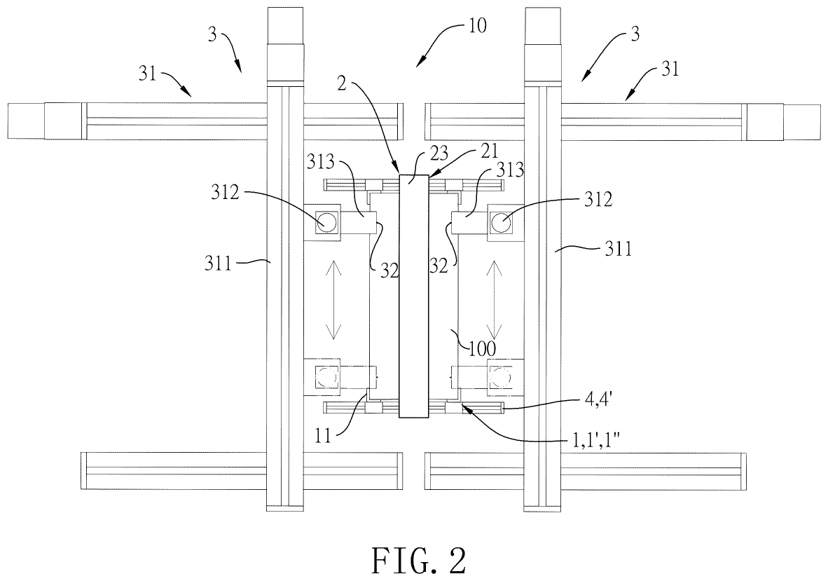

Please refer to FIGS. 2 and 4 simultaneously. The first heating source 21 can be replaced by a thermal imager 24. The detection device 10 for the electronic component 100 includes a carrier 1 or a clamp 1′, a heating module 2, a thermal imager 24, and a processing unit 25. The clamp 1′ holds the electronic component 100, wherein the electronic component 100 has a surface 100S1 and a surface 100S2. The heating module 2 is disposed at one side of the electronic component 100, and heats the surface 100S1. The thermal imager 24 is disposed at the other side of the electronic component 100, and monitors the surface 100S2 to monitor a temperature of the electronic component 100. The processing unit 25 is electrically connected to the heating module 2 and the thermal imager 24, and adjusts the heating module 2 in response to the temperature so that the temperature is stabilized in a predetermined range.

The temperature is a target temperature, which can be a temperature required by the manufacturer; for example, generally speaking, it is about 125 degrees Celsius when testing the electronic component 100. The temperature control method includes a heating start procedure, a target temperature approaching procedure, and a target temperature maintaining procedure. In the heating start procedure, the temperature monitored by the thermal imager 24 in real time is far lower than the target temperature, and the heating module 2 begins to continuously increase power for heating. In the target temperature approaching procedure, the temperature monitored by the thermal imager 24 in real time is close to the target temperature, and the heating module 2 gradually reduces the heating power. In the target temperature maintaining procedure, the thermal imager 24 monitors the temperature fluctuations in real time, and the heating module 2 continues to increase or decrease the heating power slightly to achieve a constant temperature effect. For example, the processing unit 25 can control the heating module 2. Before the thermal imager 24 detects that the temperature of the electronic component 100 has not reached 125 degrees Celsius, the processing unit 25 controls the heating module 2 to reduce its heating intensity. Before the thermal imager 24 detects that the temperature of the electronic component 100 is lower than 100 degrees Celsius, the processing unit 25 controls the heating module 2 to increase its heating intensity. The heating module 2 in FIG. 4 can only include the second heating source 22, and only the second surface 100S2 of the electronic component 100 is heated by the second heating source 22. The thermal imager 24 can monitor the temperature of the electronic component 100 in real time, and transmit the temperature data related to the electronic component 100 to the processing unit 25 in real time. The processing unit 25 can be independently configured, or built into the thermal imager 24, or configured in the heating module 2 without limitation.

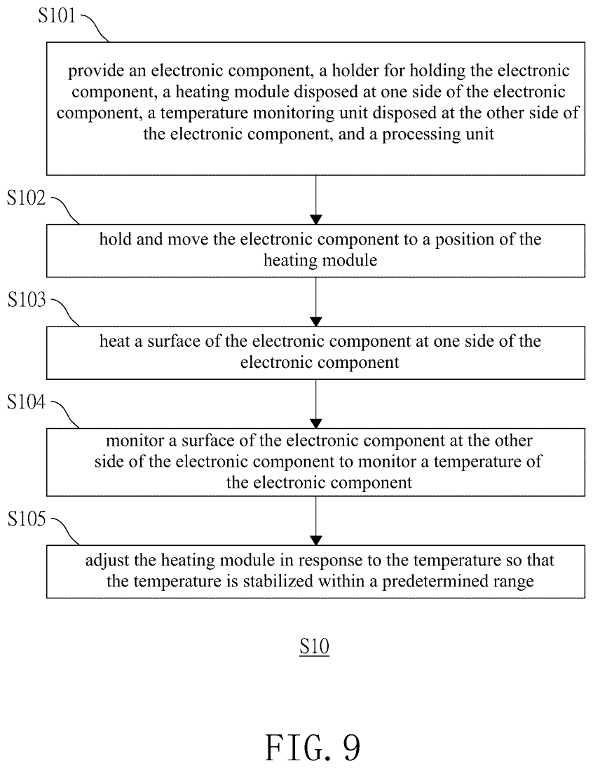

Please refer to FIG. 9, which is a method S10 for testing an electronic component according to a preferred embodiment of the present invention. Please refer to FIGS. 2, 4, and 9 simultaneously. The method S10 includes the following steps. Provide an electronic component 100, a holder 1″ for holding the electronic component 100, a heating module 2 disposed at one side of the electronic component 100, a temperature monitoring unit 26 disposed at the other side of the electronic component 100, and a processing unit 25 (S101). Hold and move the electronic component 100 to a position of the heating module 2 (S102). Heat a surface 100S2 of the electronic component 100 at one side of the electronic component 100 (S103). Monitor a surface 100S1 of the electronic component 100 at the other side of the electronic component 100 to monitor a temperature of the electronic component 100 (S104). Adjust the heating module 2 in response to the temperature so that the temperature is stabilized within a predetermined range (S105).

In any embodiment of the present invention, the method S10 further includes the following steps. Cause the processing unit to obtain a temperature datum from the thermal imager in real time, and compare the temperature datum with a target temperature and a threshold temperature so as to perform: controlling the heating module to reduce a heating intensity before the temperature data is lower than and close to the target temperature; and controlling the heating module to increase the heating intensity before the temperature data is higher than and close to the threshold temperature, wherein the heating intensity is represented by at least one of a heat source intensity, a heating duration, a heating break interval, and a distance between the electronic component and the heating module. The threshold temperature here refers to the temperature in which the heating power needs to be increased if the temperature drops too much after approaching the target temperature, which can also be set manually. For example, in order to reduce the temperature fluctuations, the threshold temperature can be set closer to the target temperature. The heat source intensity here is equivalent to the magnitude of the heating power.

In any embodiment of the present invention, the electronic component 100 is at least one of an IC carrier, a liquid crystal panel, and a circuit board. The heating module 2 includes at least one of a halogen lamp and a laser heater. The device 10 further includes a detection module 3. The detection module 3 includes a moving mechanism 31, and a detection probe 32 installed on the moving mechanism 31. The moving mechanism 31 is disposed corresponding to the clamp 1′, and drives the detection probe 32 to test the electronic component 100. The moving mechanism 3 includes a translation driving unit 311, a lifting driving unit 312 installed on the translation driving unit 311, and a fixed base 313 installed on the lifting driving unit 312, wherein the detection probe 32 is fixed on the fixed base. 313, and the translation driving unit 311 and the lifting driving unit 312 are respectively a linear slide rail and a motor-driven push rod. The device 10 further includes a moving mechanism 4', wherein the clamp 1′ is installed on the moving mechanism 4′, and can move with the moving mechanism 4′ relative to the heating module 2.

In any embodiment of the present invention, the clamp 1′ includes two symmetrical clamping elements to clamp the PCB. The PCB can be disposed perpendicular to a horizontal plane (e.g. the ground plane), and the heating module 2 can be disposed near the surface of the PCB. The irradiation direction of the heating module 2 is perpendicular to the surface of the PCB, i.e. a direction parallel to the horizontal plane. For example, when heating and testing a PCB, the PCB is fixed by the clamp 1′ in a vertical manner, which can reduce the plane space occupied by the entire heating and testing equipment. The device 10 further includes at least one detection module 3. The number of the at least one detection module 3 can be four, two of which are disposed on the left and right sides of one side of the clamp 1′, and the other two of which are disposed on the left and right sides of the other side of the clamp 1′. The device 10 in the present invention can heat the electronic component 100 and test the electronic component 100 simultaneously. The device 10 further includes a carrier 1 having a clearance area therein, and two opposite surfaces of the electronic component 100 are exposed through the clearance area.

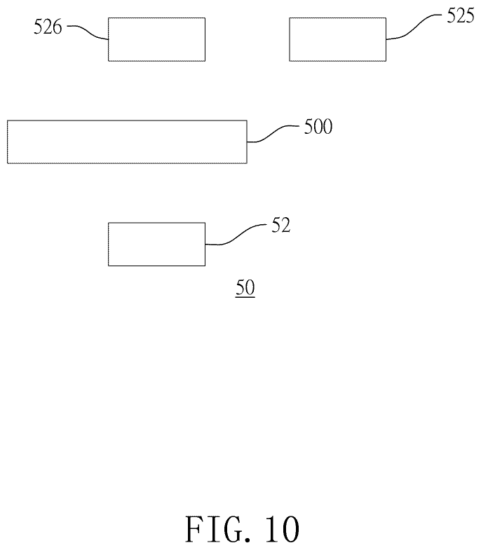

Please refer to FIG. 10, which is a device 50 for testing an electronic component 500 according to a preferred embodiment of the present invention. The device 50 includes a heating module 52, a temperature monitoring unit 526, and a processing unit 525. The heating module 52 heats the electronic component 500. The temperature monitoring unit 526 monitors a temperature of the electronic component 500. The processing unit 525 is electrically connected to the heating module 52 and the temperature monitoring unit 526, and adjusts the heating module 526 in response to the temperature so that the temperature is stabilized in a predetermined range.

In any embodiment of the invention, the temperature monitoring unit 26, 526 is a thermal imager 24. The electronic component 100, 500 is at least one of an IC carrier, a liquid crystal panel, and a circuit board. The holder 1″ is a clamp 1′ for holding the electronic component 100, 500. The electronic component 100, 500 has a surface 100S1 and a surface 100S2. The heating module 2, 52 is disposed at one side of the electronic component 100, 500, and heats the surface 100S2. The temperature monitoring unit 26, 526 is disposed at the other side of the electronic component 100, 500, and monitors the surface 100S1 to monitor a temperature of the electronic component 100, 500. The processing unit 25, 525 acquires a temperature datum from the temperature monitoring unit 26, 526 in real time to perform: controlling the heating module 2, 52 to reduce a heating intensity before the temperature datum is lower than and close to a first temperature; and controlling the heating module 2, 52 to increase the heating intensity before the temperature datum is higher than and close to a second temperature, wherein the heating intensity is represented by at least one of a heat source intensity, a heating duration, a heating break interval, and a distance between the electronic component 100, 500 and the heating module 2, 52.

In addition to being respectively disposed at both sides of the electronic component 100, the heating module 52 and the temperature monitoring unit 526 in FIG. 10 can also be disposed at the same side of the electronic component 100. Although the heating module 52 and the temperature monitoring unit 526 are located on the same side, and the configuration is relatively crowded, as long as the field of vision (FOV) of the temperature monitoring unit 526 can cover the entire area of the electronic component 100, or the distance between the temperature monitoring unit 526 and the electronic component 100 is adjusted, the heating module 526 will basically be disposed directly above the electronic component 100 so as to better regulate the temperature of the electronic component 100. This method includes adjusting the distance between the heating module 526 and the electronic component 100, and regulating the heating intensity of the heating module 526 on the electronic components 100, and the temperature monitoring unit 526 does not need to be disposed directly above the electronic components 100. On the other hand, at least one of the heating module 526 and the temperature monitoring unit 526 can be disposed above the electronic component 100.

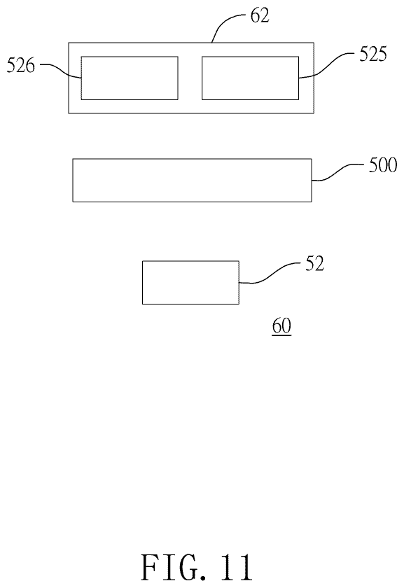

Please refer to FIG. 11, which is a device 60 for testing an electronic component 500 according to a preferred embodiment of the present invention. The device 60 includes a heating module 52 and a temperature monitoring module 62. The heating module 52 heats the electronic component 500. The temperature monitoring module 62 is electrically connected to the heating module 52, and monitors and controls a temperature of the electronic component 500.

The embodiment in FIG. 10 or 11 can be combined with the embodiment in FIGS. 1 to 9 to become a new embodiment. For example, in any embodiment of the present invention, the temperature monitoring module 62 includes a temperature monitoring unit 526 and a processing unit 525. The temperature monitoring unit 526 is a thermal imager 24. The electronic component 100, 500 is at least one of an IC carrier, an LCD panel, and a circuit board. The device 10, 50, 60 further includes a holder 1″ for holding the electronic component 100, 500. The holder 1″ is a clamp 1′ for holding the electronic component 100, 500. The holder 1″ and the heating module 2 are disposed vertically or horizontally to each other. For example, the heated surface of the PCB or IC carrier board can be disposed vertically to the ground plane. In order to simultaneously heat and monitor the temperature of the electronic component 100, 500, the holder 1″ and the heating module 2 are disposed horizontally relative to the electronic component 100, 500. When the PCB or IC carrier is disposed horizontally to the ground plane, the holder 1″ and the heating module 2 are disposed vertically relative to the electronic component 100, 500. The electronic component 100, 500 has a first surface 100S1 and a second surface 100S2. The heating module 2 includes at least one of a halogen lamp and a laser heater, and the halogen lamp is such as a halogen heating lamp tube 23. The heating module 2 is disposed above one side of the electronic component 100, 500, and heats the first surface 100S1. The temperature monitoring unit 100, 500 is disposed above the other side of the electronic component 100, 500, and monitors the second surface 100S2 to monitor a temperature of the electronic component 100, 500. The processing unit 25, 525 acquires a temperature datum from the temperature monitoring unit 26, 526 in real time to perform: controlling the heating module 2, 52 to reduce a heating intensity before the temperature datum is lower than and close to a first temperature; and controlling the heating module 2, 52 to increase the heating intensity before the temperature datum is higher than and close to a second temperature, wherein the heating intensity is represented by at least one of a heat source intensity, a heating duration, a heating break interval, and a distance between the electronic component 100, 500 and the heating module 2, 52. The device 10, 50, 60 further includes a detection module 3. The detection module 3 includes a moving mechanism 31, and a detection probe 32 installed on the moving mechanism 31. The moving mechanism 31 is disposed corresponding to the clamp 1′, and drives the detection probe 32 to test the electronic components 100, 500. The moving mechanism 31 includes a translation driving unit 311, a lifting driving unit 312 installed on the translation driving unit 311, and a fixed base 313 installed on the lifting driving unit 312, wherein the detection probe 32 is fixed on the fixed base 313, and the translation driving unit 311 and the lifting driving unit 312 are respectively a linear slide rail and a motor-driven push rod. The device 10, 50, 60 further includes a moving mechanism 4, such as a translation mechanism 4, wherein the holder 1″ is installed on the moving mechanism 4, and can move with the moving mechanism 4 relative to the heating module. 2, 52. The electronic component 100, 500 is heated and detected simultaneously. The device 10, 50, 60 further includes a carrier 1. The carrier 1 has a clearance area therein, and two opposite surfaces 100S1, 100S2 of the electronic component 100, 500 are exposed through the clearance area.

While the invention has been described in terms of what is presently considered to be the most practical and preferred embodiments, it is to be understood that the invention need not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A device for testing an electronic component, comprising:
a clamp configured to hold the electronic component having a first surface and a second surface being opposite to the first surface;
a heating module disposed at one side of the electronic component and configured to heat the first surface;
a thermal imager disposed at an opposite side of the electronic component and configured to monitor a temperature on the second surface of the electronic component; and
a processing unit electrically connected to the heating module and the thermal imager, and configured to adjust the heating module in response to the temperature to stabilize the temperature within a predetermined range.

2. The device as claimed in claim 1, wherein:
the electronic component is an IC carrier, a liquid crystal panel, or a circuit board; and
the heating module includes at least one of a halogen lamp and a laser heater.

3. The device as claimed in claim 1, further comprising:
a detection module including a first moving mechanism and a detection probe installed on the first moving mechanism, wherein the first moving mechanism is disposed corresponding to the clamp and drives the detection probe to detect the electronic components.

4. The device as claimed in claim 3, wherein:
the first moving mechanism includes a translation drive unit, a lifting drive unit installed on the translation drive unit, and a fixed base installed on the lifting drive unit, wherein the detection probe is fixed on the fixed base, and the translation drive unit and the lifting drive unit are respectively a linear slide rail and a motor-driven push rod.

5. The device as claimed in claim 3, wherein the electronic component is heated and detected simultaneously.

6. The device as claimed in claim 1, further including:
a second moving mechanism, wherein the clamp is installed on the second moving mechanism and is configured to move with the second moving mechanism relative to the heating module.

7. The device as claimed in claim 1, wherein the electronic component has a heated surface being one of the first surface and the second surface and perpendicular to a ground plane, the device further comprises a carrier having a clearance area therein, and the first and the second surfaces of the electronic component are exposed through the clearance area.

8. The device as claimed in claim 1, wherein:
the device further comprises at least one detection module, a number of the at least one detection module is four, wherein two of the detection modules are disposed at a left and a right sides of one side of the clamp, and another two detection modules are disposed at a left and a right sides of another side of the clamp.

9. The device as claimed in claim 1, wherein:
the processing unit is configured to acquire a temperature datum from the thermal imager in real time, and compare the temperature datum with a target temperature and a threshold temperature to perform:
controlling the heating module to reduce a heating intensity before the temperature datum is to be lower than and close to the target temperature; and
controlling the heating module to increase the heating intensity before the temperature datum is to be higher than and close to the threshold temperature, wherein the heating intensity is represented by at least one of a heat source intensity, a heating duration, a heating break interval, and a distance between the electronic component and the heating module.

10. A method for testing an electronic component, comprising the following steps:
providing an electronic component having one side and an opposite side, a holder for holding the electronic component, a heating module disposed at the one side of the electronic component, a temperature monitoring unit disposed at the opposite side of the electronic component, and a processing unit;
holding and moving the electronic component to a position in front of the heating module;
heating a first surface of the electronic component using the heating module;
monitoring a second surface of the electronic component using the temperature monitoring unit to monitor a temperature of the electronic component; and
adjusting the heating module in response to the temperature to stabilize the temperature within a predetermined range.

11. The method as claimed in claim 10, further comprising the following steps:
causing the processing unit to acquire a temperature datum from the thermal imager in real time, and comparing the temperature datum with a target temperature and a threshold temperature to perform the following sub-steps:
controlling the heating module to reduce a heating intensity before the temperature datum is to be lower than and close to the target temperature; and
controlling the heating module to increase the heating intensity before the temperature datum is to be higher than and close to the threshold temperature, wherein the heating intensity is represented by at least one of a heat source intensity, a heating duration, a heating break interval, and a distance between the electronic component and the heating module.

12. The method as claimed in claim 10, wherein:
the temperature monitoring unit is a thermal imager;
the electronic component is one selecting from a group consisting of an IC carrier, a liquid crystal panel, and a circuit board; and
the heating module includes at least one of a halogen lamp and a laser heater.

13. The method as claimed in claim 10, further comprising the following steps:
providing a detection module including a first moving mechanism and a detection probe installed on the first moving mechanism, wherein the first moving mechanism is disposed corresponding to the holder; and
driving the detection probe to detect the electronic components using the first moving mechanism.

14. The method as claimed in claim 10, wherein:
the first moving mechanism includes a translation drive unit, a lifting drive unit installed on the translation drive unit, and a fixed base installed on the lifting drive unit, the detection probe is fixed on the fixed base, and the translation drive unit and the lifting drive unit are respectively a linear slide rail and a motor-driven push rod; and
the method further comprises the following steps:
providing a second moving mechanism, wherein the holder is installed on the second moving mechanism and is configured to move with the second moving mechanism relative to the heating module

15. The method as claimed in claim 10, wherein:
the electronic component has a heated surface being one of the first surface and the second surface and perpendicular to a ground plane; and
the electronic component is heated and detected simultaneously

16. A device for testing an electronic component, comprising:
a heating module configured to heat the electronic component; and
a temperature monitoring module electrically connected to the heating module and configured to monitor and control a temperature of the electronic component.

17. The device as claimed in claim 16, wherein:
the temperature monitoring module comprises a temperature monitoring unit and a processing unit;
the temperature monitoring unit is a thermal imager;
the electronic component is an IC carrier, a liquid crystal panel, or a circuit board;
the device further comprises a holder for holding the electronic component;
the holder is a clamp for clamping the electronic device;
the electronic component has a heated surface disposed perpendicular to a ground plane;
the electronic component has a first surface and a second surface;
the heating module includes at least one of a halogen lamp and a laser heater;
the heating module is disposed at one side of the electronic component and configured to heat the first surface; and
the temperature monitoring unit is disposed at another side of the electronic component and configured to monitor the second surface to monitor the temperature of the electronic component.

18. The device as claimed in claim 17, wherein:
the processing unit is configured to acquire a temperature datum from the thermal imager in real time, and compare the temperature datum with a target temperature and a threshold temperature to perform:
controlling the heating module to reduce a heating intensity before the temperature datum is to be lower than and close to the target temperature; and
controlling the heating module to increase the heating intensity before the temperature datum is to be higher than and close to the threshold temperature, wherein the heating intensity is represented by at least one of a heat source intensity, a heating duration, a heating break interval, and a distance between the electronic component and the heating module.

19. The device as claimed in claim 16, wherein:
the device further comprises a detection module including a first moving mechanism and a detection probe installed on the first moving mechanism, the first moving mechanism is disposed corresponding to the clamp and is configured to drive the detection probe to detect the electronic components; and
the first moving mechanism includes a translation drive unit, a lifting drive unit installed on the translation drive unit, and a fixed base installed on the lifting drive unit, wherein the detection probe is fixed on the fixed base, and the translation drive unit and the lifting drive unit are respectively a linear slide rail and a motor-driven push rod.

20. The device as claimed in claim 16, wherein:
the device further comprises a second moving mechanism, wherein the clamp is installed on the second moving mechanism and is configured to move with the second moving mechanism relative to the heating module;
the electronic component is heated and detected simultaneously; and
the device further comprises a carrier having a clearance area therein, and two opposite surfaces of the electronic component are exposed through the clearance area.
